(19) United States
(12) Patent Application Publication
(10) Pub. No.: US 2025/0157981 A1
(43) Pub. Date: May 15, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Naohiro OGUSHI, Tokyo (JP); Yuji IMOTO, Tokyo (JP); Taishi SASAKI, Tokyo (JP)

(73) Assignee: Mitsubishi Electric Corporation, Tokyo (JP)

(21) Appl. No.: 18/726,265

(22) PCT Filed: Apr. 8, 2022
(86) PCT No.: PCT/JP2022/017378

§ 371 Date: Jul. 2, 2024

(51) Int. Cl. H01L 23/00

(52) U.S. Cl. CPC H01L 24/81; H01L 24/13; H01L 2224/13082; H01L 2224/81455

(57) ABSTRACT

An object is to provide a technique capable of reducing a void in a semiconductor device. A semiconductor device includes a plating film, a semiconductor element, and a spacer. The semiconductor element is provided on an upper side of the plating film. The spacer includes a first wire bump. The spacer provides a gap between the plating film and the semiconductor element. A lower surface of the first wire bump does not have contact with the plating film, or a part of the lower surface of the first wire bump located on an outer side of an outer surrounding part of the plating film does not have contact with the plating film.

### TECHNICAL FIELD

The present disclosure relates to a semiconductor device and a method of manufacturing the semiconductor device.

### BACKGROUND ART

Various techniques are proposed as with Patent Document 1, for example, for a

power semiconductor device as a type of a semiconductor device. Also proposed is a technique of providing a gap between a semiconductor element and a plating film by proving a wire bump between the semiconductor element and the plating film, for example.

### PRIOR ART DOCUMENTS

### Patent Document(s)

Patent Document 1: Japanese Patent Application Laid-Open No. 2019-110317

### SUMMARY

### Problem to be Solved by the Invention

However, when a wire bump is formed on the plating film by wedge bonding, for example, the wire bump and a cutter using for forming the wire bump supply stress to the plating film, thus a crack which is hardly detected visually, for example, occurs in the plating film in some cases. As a result, there is a problem that when a bonding member such as a solder layer is formed, gas in the plating film and gas in an interface between the plating film and a base are discharged from around the wire bump and a void is formed in the bonding member.

The present disclosure therefore has been made to solve the above problems, and it is an object to provide a technique capable of reducing a void in a semiconductor device.

### Means to Solve the Problem

A semiconductor device according to the present disclosure includes a plating film, a semiconductor element provided on an upper side of the plating film, and a spacer including a first wire bump and providing a gap between the plating film and the semiconductor element, wherein a lower surface of the first wire bump does not have contact with the plating film, or a part of the lower surface of the first wire bump located on an outer side of an outer surrounding part of the plating film does not have contact with the plating film.

### Effects of the Invention

According to the present disclosure, the lower surface of the first wire bump does not have contact with the plating film, or a part of the lower surface of the first wire bump located on an outer side of an outer surrounding part of the plating film does not have contact with the plating film. According to such a configuration, a void in the semiconductor device can be reduced.

These and other objects, features, aspects and advantages of the present disclosure will become more apparent from the following detailed description of the present disclosure when taken in conjunction with the accompanying drawings.

### BRIEF DESCRIPTION OF DRAWINGS

FIG. 1 A cross-sectional view illustrating a configuration of a semiconductor device according to an embodiment 1.

FIG. 2 A plan view illustrating the configuration of the semiconductor device according to the embodiment 1.

FIG. 3 A cross-sectional view illustrating a configuration of a related semiconductor device.

FIG. 4 A cross-sectional view for describing a problem point occurring in manufacturing the related semiconductor device.

FIG. 5 A plan view illustrating a configuration of a semiconductor device according to an embodiment 2.

FIG. 6 A cross-sectional view illustrating a configuration of a semiconductor device according to an embodiment 3.

FIG. 7 A plan view illustrating the configuration of the semiconductor device according to the embodiment 3.

FIG. 8 A cross-sectional view illustrating a configuration of a semiconductor device according to an embodiment 4.

FIG. 9 A plan view illustrating the configuration of the semiconductor device according to the embodiment 4.

FIG. 10 A cross-sectional view illustrating a configuration of a semiconductor device according to an embodiment 5.

FIG. 11 A plan view illustrating a configuration of a semiconductor device according to the embodiment 5.

FIG. 12 A plan view illustrating a configuration of a semiconductor device according to an embodiment 6.

### DESCRIPTION OF EMBODIMENT(S)

Embodiments are described with reference to the appended diagrams hereinafter. Features described in each embodiment described below is exemplification, thus all features are not necessarily applied. The same or similar reference numerals will be assigned to similar constituent elements in a plurality of embodiments in the description hereinafter, and the different constituent elements are mainly described hereinafter. A specific position and direction such as “upper”, “lower”, “left”, “right”, “front”, or “back”, for example, may not necessarily coincide with a position and direction in an actual implementation in the description hereinafter.

### Embodiment 1

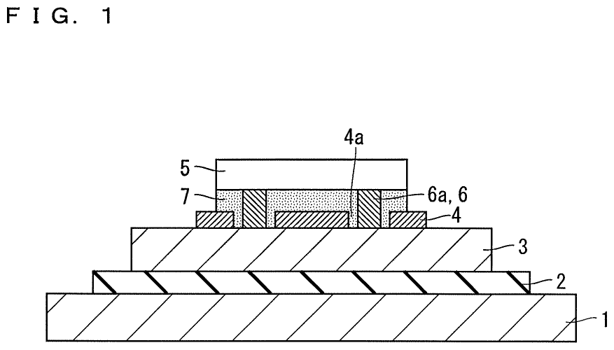

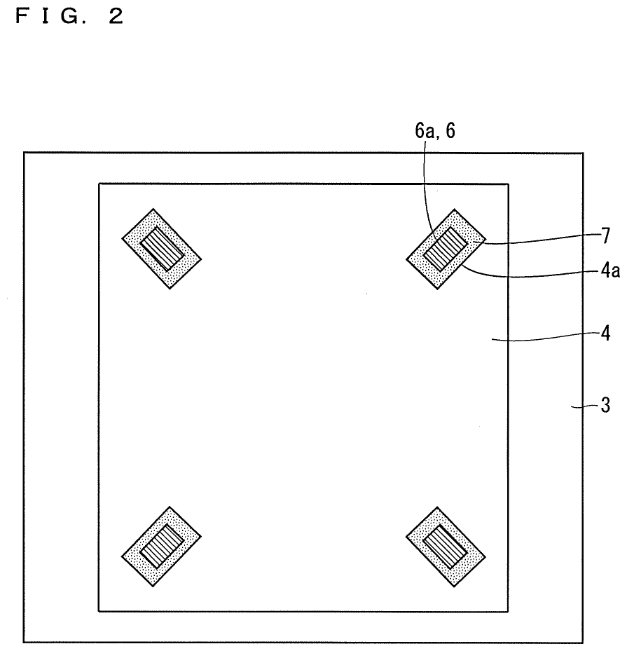

FIG. 1 is a cross-sectional view illustrating a configuration of a semiconductor device according to the present embodiment 1, and FIG. 2 is a plan view illustrating the configuration thereof. The semiconductor device according to the present disclosure is applied to a power semiconductor device, for example.

The semiconductor device in FIG. 1 includes a cooling mechanism 1, an insulating member 2, a conductive member 3, a plating film 4, a semiconductor element 5, a spacer 6, and a solder layer 7.

The cooling mechanism 1 cools the semiconductor element 5 via the insulating member 2 and the conductive member 3, for example. The cooling mechanism 1 may be provided with a cooling fin not shown in the diagrams.

The insulating member 2 is provided on the cooling mechanism 1. A material of the insulating member 2 includes ceramic, for example.

The conductive member 3 is provided on the insulating member 2. A material of the conductive member 3 may be a material such as pure aluminum (Al) or aluminum alloy which is hardly soldered, or may also be copper (Cu), for example,

The plating film 4 is provided on the conductive member 3. In other words, the conductive member 3 is provided on a lower side of the plating film 4. The plating film 4 is provided with a through hole 4a partially exposing the conductive member 3. In the present embodiment 1, the plating film 4 is a non-electrolytic plating film including nickel and phosphorus, and a concentration of phosphorus is equal to or larger than 5 wt %. However, the plating film 4 is not limited thereto. The concentration of phosphorus can be measured by a X-ray fluorescence spectrometer, for example,

The semiconductor element 5 is provided on an upper side of the plating film 4. The semiconductor element 5 is a metal oxide semiconductor field effect transistor (MOSFET), an insulated gate bipolar transistor (IGBT), a reverse conducting IGBT (RC-IGBT), a Schottky barrier diode (SBD), and a PN junction diode (PND), for example. A material of the semiconductor element 5 may be normal silicon (Si), or may also be wide bandgap semiconductor such as silicon carbide (SiC), gallium nitride (GaN), or diamond. When the semiconductor element 5 is made up of wide bandgap semiconductor, a stable operation under high temperature and high voltage and increase of switching speed can be achieved.

The spacer 6 provides a constant gap between the plating film 4 and the semiconductor element 5. For example, as illustrated in FIG. 2, the spacer 6 is provided to correspond to four corners of a quadrangular plating film 4 in a plan view. According to such a configuration, variation of the gap between the plating film 4 and the semiconductor element 5 can be suppressed.

The spacer 6 includes a first wire bump 6a. In the present embodiment 1, the spacer 6 includes only the first wire bump 6a, however, as describe hereinafter, the spacer 6 may further include a constituent element other than the first wire bump 6a.

A material of the first wire bump 6a includes aluminum (Al) or copper (Cu), for example. In the present embodiment 1, as illustrated in FIG. 1, the first wire bump 6a is provided on an inner side of an outer surrounding part of the plating film 4. Then, a lower surface of the first wire bump 6a does not have contact with the plating film 4, but has contact with the conductive member 3 through the through hole 4a of the plating film 4.

The solder layer 7 is a bonding member bonding the plating film 4 and the semiconductor element 5, and is provided to the gap between the plating film 4 and the semiconductor element 5. The bonding member is not limited to the solder layer 7.

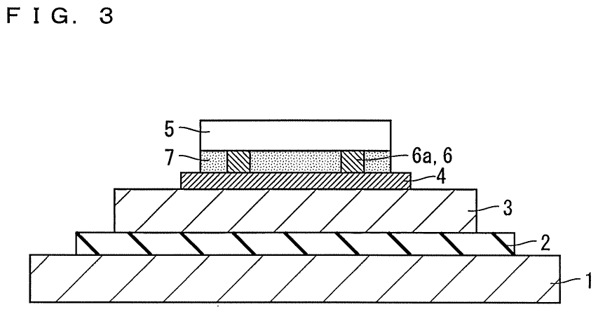

Described next is a semiconductor device relating to the semiconductor device according to the present embodiment 1 (referred to as “the related semiconductor device” hereinafter). FIG. 3 is a cross-sectional view illustrating a configuration of a related semiconductor device. In the related semiconductor device, the lower surface of the first wire bump 6a as the spacer 6 has wholly contact with the plating film 4 in the related semiconductor device.

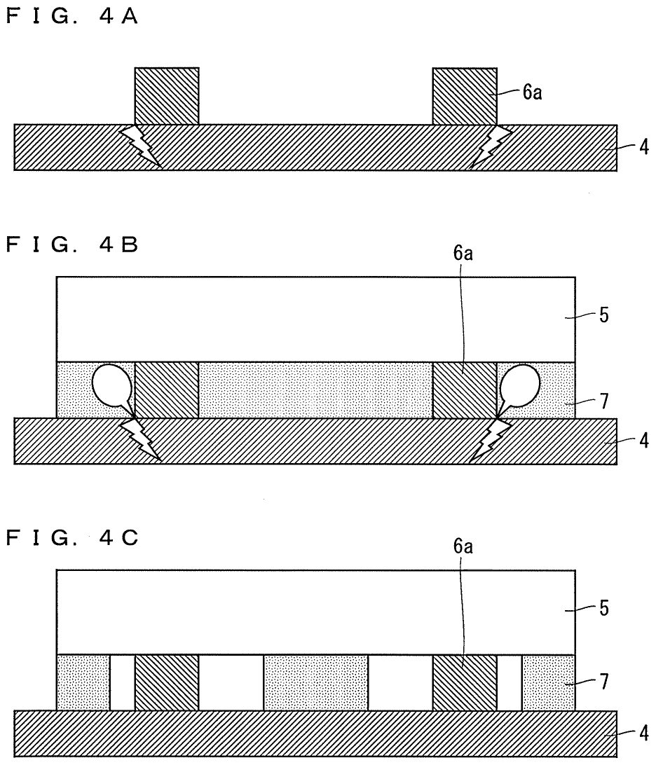

FIG. 4 is a cross-sectional view for describing a problem point occurring in manufacturing the related semiconductor device. As illustrated in FIG. 4(a), when the first wire bump 6a is formed to have contact with the plating film 4 by wedge bonding, for example, stress is applied to the plating film 4 in contacting the first wire bump 6a and the plating film 4 and cutting the first wire bump 6a by a cutter. A crack which is hardly detected visually, for example, occurs in the plating film 4 around the first wire bump 6a due to this stress in some cases. When the solder layer 7, for example, is formed on the plating film 4 in this state, gas in the plating film 4 and gas in an interface between the plating film 4 and the conductive member 3 are discharged from around the first wire bump 6a as illustrated in FIG. 4(b). As a result, a void is formed in the solder layer 7 in some cases as illustrated in FIG. 4(c).

In contrast, according to the present embodiment 1, the lower surface of the first wire bump 6a does not have contact with the plating film 4, but has contact with the conductive member 3 through the through hole 4a of the plating film 4. According to such a configuration, a crack of the plating film 4, for example, is suppressed, and discharge of gas from the plating film 4 around the first wire bump 6a is suppressed, thus a void in the solder layer 7 can be reduced. As a result, mechanical strength of the semiconductor device can be increased. According to the configuration that the cooling mechanism 1 is provided as illustrated in FIG. 1, thermal conductivity between the cooling mechanism 1 and the semiconductor element 5 can be increased, thus heat radiation properties of the semiconductor element 5 can be increased.

A lateral part of the first wire bump 6a may have contact with the plating film 4 as long as the lower surface of the first wire bump 6a does not have contact with the plating film 4. However, it is preferable that the lateral part of the first wire bump 6a does not have contact with the plating film 4 as illustrated in FIG. 1 so that the lower surface of the first wire bump 6a does not have contact with the plating film 4 even when production tolerance occurs,

In the present embodiment 1, the solder layer 7 provided in the gap between the plating film 4 and the semiconductor element 5 is further included, and the material of the conductive member 3 includes aluminum or aluminum alloy. According to such a configuration, adhesion strength between the solder layer 7 and the conductive member 3 can be increased by the plating film 4, thus a material such as pure aluminum (Al) or aluminum alloy which is hardly soldered can be used for the conductive member 3.

In the present embodiment 1, the plating film 4 is a non-electrolytic plating film including nickel (Ni) and phosphorus (P), and a concentration of phosphorus is equal to or larger than 5 wt %. According to such a configuration, Ni plating has a amorphas structure, thus gas can be discharged from the plating film 4 at a lower temperature than a solder melting temperature. As a result, gas can be discharged at a time of start of forming the solder layer 7, thus the gas discharged at the time of start can be exhausted from the solder layer 7 at a time of completion of forming the solder layer 7. As a result, a void in the solder layer 7 can be reduced.

### Embodiment 2

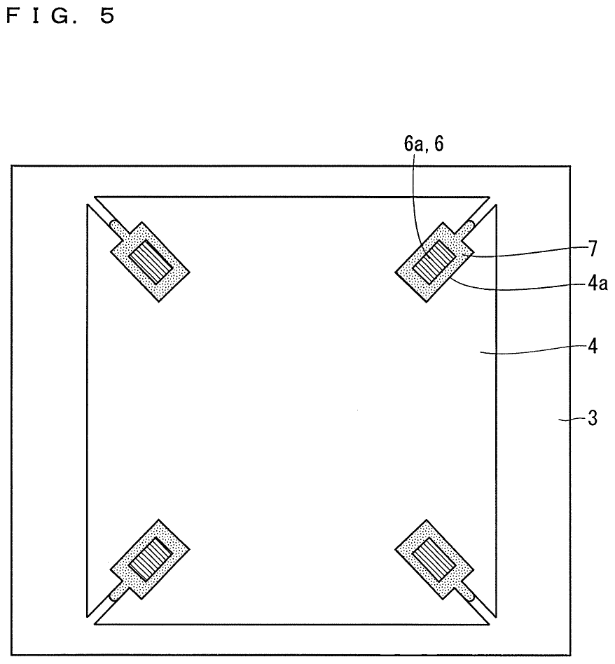

FIG. 5 is a plan view illustrating a configuration of a semiconductor device according to the present embodiment 2.

In the present embodiment 2, the through hole 4a of the plating film 4 is communicated with the outer surrounding part of the plating film 4 as illustrated in FIG. 5. According to such a configuration, even when gas is discharged from the plating film 4 around the first wire bump 6a, the gas can be easily exhausted from the solder layer 7 to the outer surrounding part of the plating film 4, thus a void in the solder layer 7 can be reduced.

### Embodiment 3

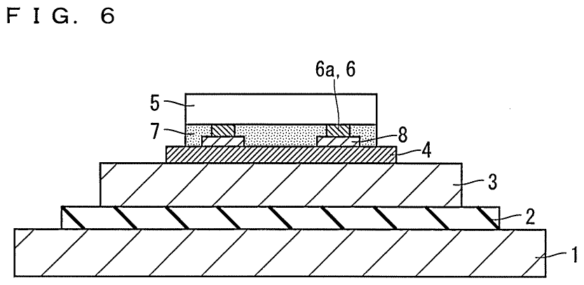

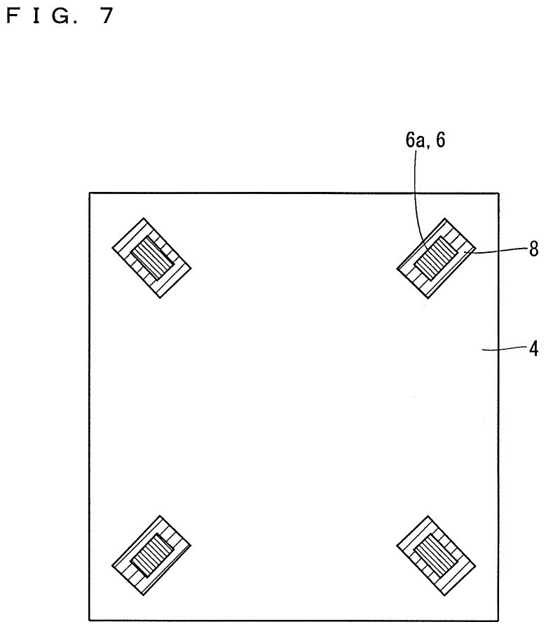

FIG. 6 is a cross-sectional view illustrating a configuration of a semiconductor device according to the present embodiment 3, and FIG. 7 is a plan view illustrating the configuration thereof.

Differing from the embodiment 1, the through hole 4a is not substantially provided to the plating film 4 in the present embodiment 3. In the meanwhile, a multilayer plating film 8 provided on the plating film 4 is added in the semiconductor device according to the present embodiment 3. The lower surface of the first wire bump 6a does not have contact with the plating film 4, but has contact with the multilayer plating film 8.

The multilayer plating film 8 has higher rigidity than the plating film 4, thus according to the configuration of the present embodiment 3 described above, a void in the solder layer 7 can be reduced in the manner similar to the embodiment 1. The through hole 4a needs not be provided to the plating film 4, thus the manufacturing process can be simplified. When a material having high heat radiation properties is used as the material of the multilayer plating film 8, heat radiation properties of the semiconductor device can be increased.

### Embodiment 4

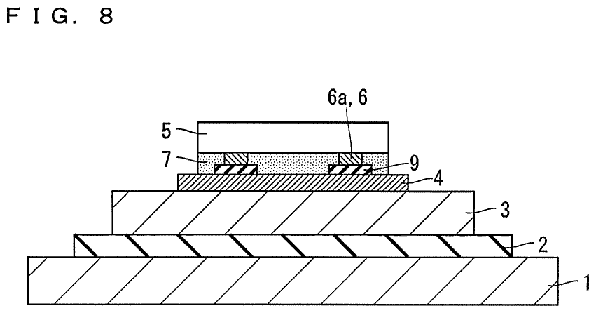

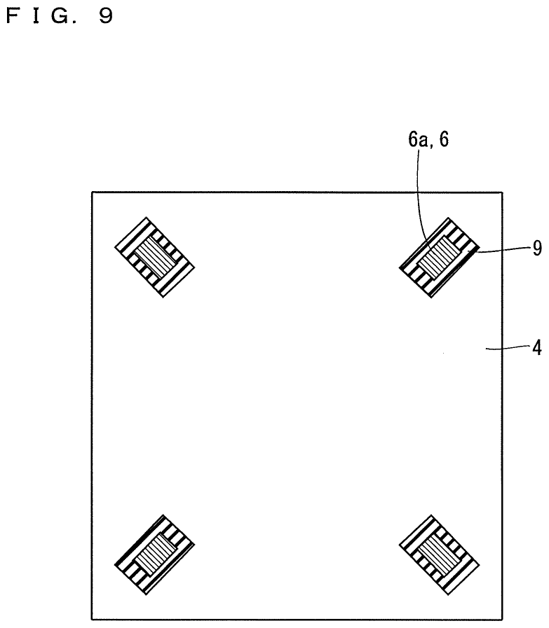

FIG. 8 is a cross-sectional view illustrating a configuration of a semiconductor device according to the present embodiment 4, and FIG. 9 is a plan view illustrating the configuration thereof.

Differing from the embodiment 1, the through hole 4a is not substantially provided to the plating film 4 in the present embodiment 4. In the meanwhile, an oxide film 9 as an insulating film provided on the plating film 4 is added in the semiconductor device according to the present embodiment 4. The lower surface of the first wire bump 6a does not have contact with the plating film 4, but has contact with the oxide film 9. The oxide film 9 may be formed by oxidizing the plating film 4.

The oxide film 9 has higher rigidity than the plating film 4, thus according to the configuration of the present embodiment 4 described above, a void in the solder layer 7 can be reduced in the manner similar to the embodiment 1. The through hole 4a needs not be provided to the plating film 4, thus the manufacturing process can be simplified.

### Embodiment 5

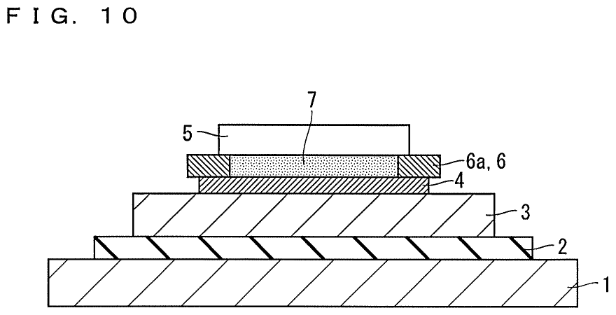

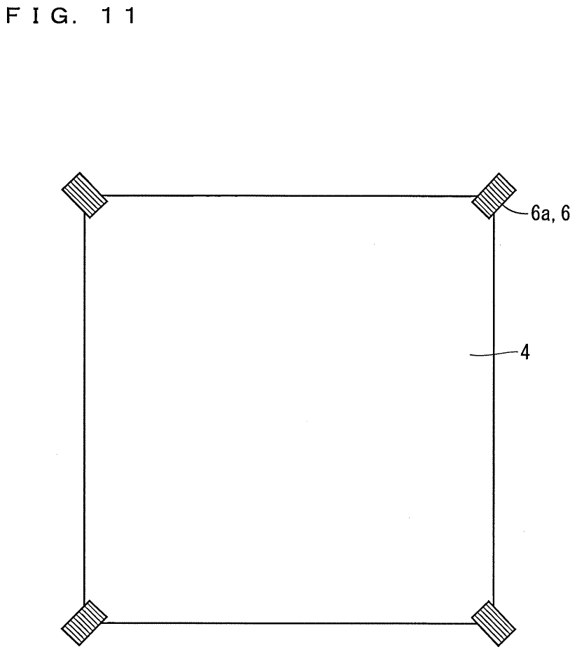

FIG. 10 is a cross-sectional view illustrating a configuration of a semiconductor device according to the present embodiment 5, and FIG. 11 is a plan view illustrating the configuration thereof.

Differing from the embodiment 1, the through hole 4a is not substantially provided to the plating film 4 in the present embodiment 5. In the meanwhile, as illustrated in FIG. 10, a part of the lower surface of the first wire bump 6a located on an outer side of the outer surrounding part of the plating film 4 does not have contact with the plating film 4. A remaining part of the lower surface of the first wire bump 6a has contact with the plating film 4. That is to say, the first wire bump 6a is provided over an outline of the plating film 4 in a plan view.

According to such a configuration of the present embodiment 4, a part of the lower surface of the first wire bump 6a does not have contact with the plating film 4, thus a void in the solder layer 7 can be reduced compared with a configuration that the lower surface of the first wire bump 6a has wholly contact with the plating film 4 (configuration in FIG. 3).

Even when gas is discharged from the plating film 4 around the first wire bump 6a, the gas can be easily exhausted from the solder layer 7 to the outer surrounding part of the plating film 4, thus a void in the solder layer 7 can be reduced. The through hole 4a needs not be provided to the plating film 4, thus the manufacturing process can be simplified.

### Embodiment 6

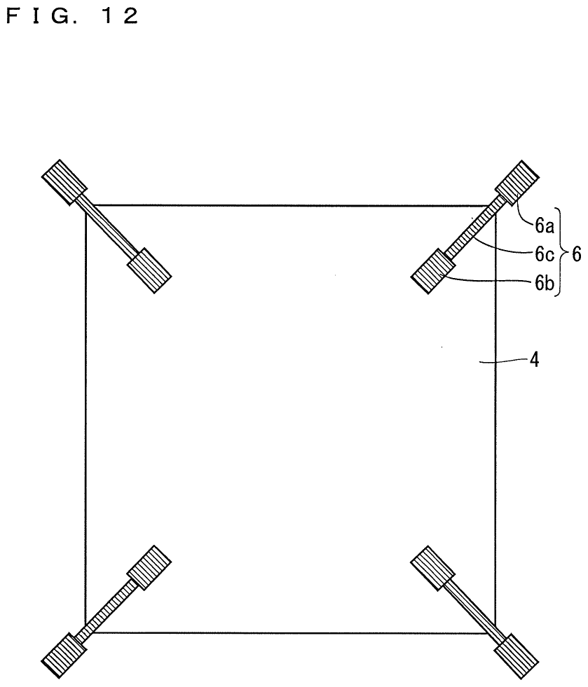

FIG. 12 is a plan view illustrating a configuration of a semiconductor device according to the present embodiment 6.

Differing from the embodiment 1, the through hole 4a is not substantially provided to the plating film 4 in the present embodiment 6. In the meanwhile, in the semiconductor device according to the present embodiment 6, the spacer 6 includes the first wire bump 6a, a second wire bump 6b, and a wire 6c, and the second wire bump 6b is connected via the wire 6c. The lower surface of the first wire bump 6a is located on the outer side of the outer surrounding part of the plating film 4 and does not have contact with the plating film 4, and a lower surface of the second wire bump 6b has contact with the plating film 4. That is to say, the wire 6c connecting the first wire bump 6a and the second wire bump 6b is provided over the outline of the plating film 4 in a plan view.

According to such a configuration of the present embodiment 6, the lower surface of the first wire bump 6a does not have contact with the plating film 4, thus a void in the solder layer 7 can be reduced compared with a configuration that the lower surface of the first wire bump 6a has wholly contact with the plating film 4. A range of the spacer 6 in a plan view can be widened, thus even when a positional deviation of the semiconductor element 5 in a plan view occurs to some extent, the semiconductor element 5 can have contact with the spacer 6, thus variation of the gap between the plating film 4 and the semiconductor element 5 can be suppressed. The through hole 4a needs not be provided to the plating film 4, thus the manufacturing process can be simplified.

The first wire bump 6a is preferably formed after the second wire bump 6b is formed. In a case of such a configuration, cutting can be performed on the outer side of the outer surrounding part of the plating film 4 by the cutter after the first wire bump 6a located on the outer side of the outer surrounding part of the plating film 4 is formed. Thus, a crack of the plating film 4, for example, is suppressed, thus a void in the solder layer 7 can be reduced.

Each embodiment and each modification example can be arbitrarily combined, or each embodiment and each modification can be appropriately varied or omitted.

The foregoing description is in all aspects illustrative and does not restrict the disclosure. It is therefore understood that numerous modifications not exemplified can be devised.

### Explanation Of Reference Signs

3 conductive member, 4 plating film, 4a through hole, 5 semiconductor element, 6 spacer, 6a first wire bump, 6b second wire bump, 6c wire, 7 solder layer, 8 multilayer plating layer, 9 oxide film.

1. A semiconductor device, comprising:
a plating film;
a semiconductor element provided on an upper side of the plating film; and
a spacer including a first wire bump and providing a gap between the plating film and the semiconductor element, wherein
a lower surface of the first wire bump does not have contact with the plating film, or a part of the lower surface of the first wire bump located on an outer side of an outer surrounding part of the plating film does not have contact with the plating film.

2. The semiconductor device according to claim 1, further comprising
a conductive member provided on a lower side of the plating film, wherein
the lower surface of the first wire bump does not have contact with the plating film, but has contact with the conductive member through a through hole provided to the plating film.

3. The semiconductor device according to claim 2, further comprising
a solder layer provided to the gap between the plating film and the semiconductor element, wherein
a the material of the conductive member includes aluminum or aluminum alloy.

4. The semiconductor device according to claim 2, wherein
the through hole of the plating film is communicated with an outer surrounding part of the plating film.

5. The semiconductor device according to claim 1, further comprising
a multilayer plating film provided on the plating film, wherein
the lower surface of the first wire bump does not have contact with the plating film, but has contact with the multilayer plating film.

6. The semiconductor device according to claim 1, further comprising
an insulating film provided on the plating film, wherein
the lower surface of the first wire bump does not have contact with the plating film, but has contact with the insulating film.

7. The semiconductor device according to claim 1, wherein
the part of the lower surface of the first wire bump does not have contact with the plating film, and
a remaining part of the lower surface of the first wire bump has contact with the plating film.

8. The semiconductor device according to claim 1, wherein
the spacer further includes a second wire bump connected to the first wire bump via a wire,
the lower surface of the first wire bump is located on an outer side of the outer surrounding part of the plating film, and does not have contact with the plating film, and
the lower surface of the second wire bump has contact with the plating film.

9. The semiconductor device according to claim 1, wherein
the plating film is a non-electrolytic plating film including nickel and phosphorus, and a concentration of phosphorus is equal to or larger than 5 wt %.

10. A method of manufacturing the semiconductor device according to claim 8, wherein
the first wire bump is formed after the second wire bump is formed.
